(19) United States
(12) Patent Application Publication
(10) Pub. No.: US 2017/0263501 A1
(43) Pub. Date: Sep. 14, 2017

(54) ELEMENT CHIP AND METHOD FOR MANUFACTURING THE SAME

(71) Applicant: Panasonic Intellectual Property Management Co., Ltd., Osaka (JP)

(72) Inventors: BUNZI MIZUNO, Nara (JP); SHOGO OKITA, Hyogo (JP); NORIYUKI MATSUBARA, Osaka (JP); ATSUSHI HARIKAI, Osaka (JP); MITSURU HIROSHIMA, Osaka (JP)

(21) Appl. No.: 15/427,380

(22) Filed: Feb. 8, 2017

(30) Foreign Application Priority Data
Mar. 11, 2016 (JP) 2016-048005

(51) Int. Cl. H01L 21/78; H01L 29/30; H01L 23/31; H01L 21/56; H01L 21/311

(52) U.S. Cl. CPC H01L 21/78; H01L 21/56; H01L 21/311; H01L 23/3171; H01L 29/30

(57) ABSTRACT

A method for manufacturing an element chip includes a laser dicing step of dividing the substrate to a plurality of element chips including the element region by irradiating the dividing region of the substrate with laser light, in a state of supported by a supporting member and forming a damaged region on an end surface of the element chip. Furthermore, the method for manufacturing an element chip includes a protection film stacking step of stacking a protection film on the first main surface and the end surface of the element chip, after the laser dicing step and a protection film etching step of removing the protection film stacked on the first main surface through etching the protection film anisotropically by exposing the element chip to plasma, after the protection film stacking, step and remaining the protection film for covering the damaged region.

### BACKGROUND

1. Technical Field

The present disclosure relates to an element chip and a method for manufacturing the same and, in particular, a method for manufacturing an element chip excellent in flexural strength.

2. Description of the Related Art

An element chip is manufactured by dicing substrate 30 including first layer 31 that is a semiconductor layer and second layer 32 including an insulating film as illustrated in FIGS. 5A and 5B. Substrate 30 includes dividing region R11 for dividing substrate 30 and a plurality of element regions R12 to be defined by dividing region R11 (FIG. 5A). By removing dividing region R11 of substrate 30, substrate 30 is diced and a plurality of element chips 130 are formed. PTL 1 discloses that substrate 30 is diced by removing dividing region R11 with laser light L (FIG. 5B).

### CITATION LIST

### Patent Literature

PTL 1: Japanese Patent. Unexamined Publication No. 2000-31115

### SUMMARY

In the laser dicing step (FIG. 5B), generally, damaged region DR is formed on an end surface of diced element chip 130 and substrate 30 due to thermal influence. In a case of crystal disorder or polycrystalline, coarsening of crystal grains is observed in damaged region DR. Therefore, in particular, damaged region DR exposing to the end surface of first layer 31 tends to be a starting poring for cleavage of first layer 31. Accordingly, deflective strength of element chip 130 is easily reduced.

An aspect of the present disclosure relates to a method for manufacturing an element chip including a step of preparing a substrate, a laser dicing step, a protection film stacking step after the laser dicing step, and a protection film etching step after the protection film stacking step. In the step of preparing the substrate, a substrate which has a first main surface and a second main surface and includes a first layer that is a semiconductor layer, a second layer including an insulating film formed on a side of the first main surface of the first layer, a plurality of element regions, and a dividing region for defining the element region, is prepared. In the laser dicing step, the substrate is divided to a plurality of element chips including the element region by irradiating the dividing region with laser light from the side of the first main surface, in a state where the second main surface is supported by a supporting member and a damaged region is formed on an end surface of the element chip. In the protection film stacking step, a protection film is stacked on the first main surface and the end surface of the element chip. In the protection film etching step, the protection film stacked on the first main surface is removed through etching the protection film anisotropically by exposing the element chip to plasma and the protection film for covering the damaged region is remained.

Another aspect of the present disclosure relates to an element chip including a first layer that is a semiconductor layer having a lamination surface and a surface facing the lamination surface, a second layer including an insulating film which is laminated on the lamination surface, a damaged region formed on end surfaces of the first layer and the second layer, and a protection film for covering the damaged region formed on end surfaces of the first layer and the second layer.

According to the present disclosure, since the damaged region which is to be a starting point of cleavage is covered with a protection film, flexural strength of an element chip can be improved.

### BRIEF DESCRIPTION OF THE DRAWINGS

FIG. 1A is a cross-sectional view illustrating a step of a manufacturing method according to an exemplary embodiment of the present disclosure;

FIG. 1B is a cross-sectional view illustrating a step of the manufacturing method;

FIG. 1C is a cross-sectional view illustrating a step of the manufacturing method;

FIG. 1D is a cross-sectional view illustrating a step of the manufacturing method;

FIG. 2 is a cross-sectional view illustrating an element chip according to the exemplary embodiment of the present disclosure;

FIG. 3A is a top surface vies illustrating a transfer carrier according to the exemplary embodiment of the present disclosure.

FIG. 3B is a cross-sectional view of the transfer carrier taken along line 3B-3B in FIG. 3A.

FIG. 4 is a conceptual diagram illustrating a schematic structure of a plasma processing device in a cross section;

FIG. 5A is a cross-sectional view illustrating a step of a manufacturing method of an element chip in the related art; and

FIG. 5B is a cross-sectional view illustrating a step of the manufacturing method.

### DETAILED DESCRIPTION

In the present exemplary embodiment, by a method that a damaged region is not exposed with laser light from a diced element chip, that is, a method for interposing the damaged region to the element chip, the substrate is diced. That is, an element chip is manufactured by a method including a step of preparing a substrate, a laser dicing step, a protection film stacking step, and protection film etching step. The step of preparing is a step of preparing a substrate which has a first main surface and a second main surface and includes a first layer that is a semiconductor layer, a second layer including an insulating film formed on a side of the first main surface of the first layer, a plurality of element regions, and a dividing region for defining each of the element regions, is prepared. The laser dicing step is a step of dividing the substrate to a plurality of element chips including the element regions by irradiating the dividing region with laser light from the side of the first main surface, in a state where the second main surface is supported by a supporting member and forming a damaged region on an end surface of each of the element chips. The protection film stacking step is a step of stacking a protection film on the first main surface and the end surface of each of the element chips, after the laser dicing step. The protection film etching step is a step of removing the protection film stacked on the first main surface through etching the protection film anisotropically by exposing each of the element chips to plasma, after the protection film stacking step and remaining the protection film for covering the damaged region.

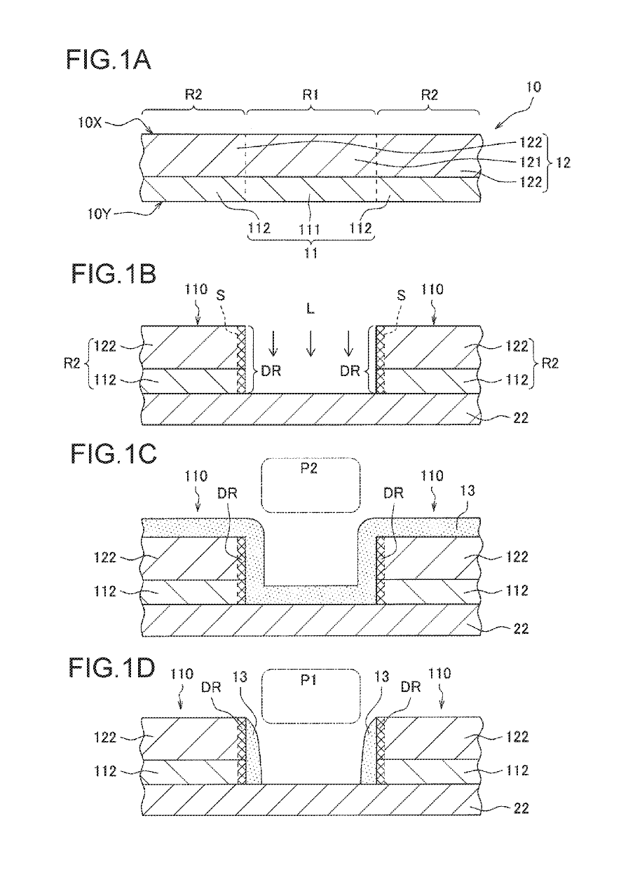

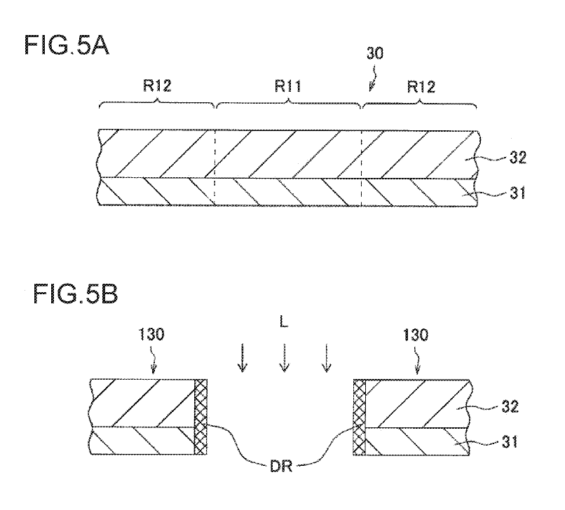

A manufacturing method according to the present exemplary embodiment will be described with reference to FIGS. 1A to 1D. FIGS. 1A to 11) are cross-sectional views illustrating each step of the manufacturing method according to the present exemplary embodiment.

### (1) Preparing Step

Firstly, substrate 10 to be diced is prepared (FIG. 1A). Substrate 10 has first main surface lox and second main surface NY and includes first layer 11 that is a semiconductor layer and second layer 12 including an insulating layer which is formed on first main surface 10X side of first layer 11. In addition, substrate 10 is separated into dividing region R1 and the plurality of element regions R2 which are defined by dividing region R1. Accordingly, first layer 11 includes first dividing region 111 corresponding to dividing region R1 and a plurality of first element regions 112 corresponding to element regions R2. Second layer 12 includes a second dividing region 121 corresponding to dividing region R1 and a plurality of second element regions 122 corresponding to element regions R2. A semiconductor circuit, an electric component element, and a circuit layer such as an electronic component element, MEMS (which are not illustrated) may be formed on element regions R2 of substrate 10 (first element region 112 and second element region 122).

First layer 11 is a semiconductor layer formed of, for example, silicon (Si), gallium arsenide (GaAs), gallium nitride (GaN), silicon carbide (SiC), or the like. Second layer 12 includes at least an insulating film. For example, the insulating layer includes silicon dioxide (SiO₂), silicon nitride (Si₃N₄), lithium tantalate (LiTaO₃), lithium niobate (LiNbO₃), or the like. Second layer 12 may include a multilayer wiring layer (for example, a laminate of a low-k (low dielectric constant) and a copper (Cu) wiring layer), a metal material, a resin protective layer (for example, polyimide), a resist, or the like addition to the insulating film.

### (2) Laser Dicing Step

In the laser dicing step, substrate 10 is divided to a plurality of element chips 110 including element regions R2 by irradiating second dividing region 121 with laser light L from first main surface 10X side (FIG. 1B). A center wavelength of laser light L is not particularly limited, and is within a range of 350 to 600 nm inclusive, for example.

By the radiation of laser light L, damaged region DR which is thermally affected by laser light L is formed on the end surface of formed element chip 110. In FIGS. 13 to 11), boundary surface S between damaged region DR and the other regions is indicated by a broken line. The thickness of damaged region DR is changed depending on a radiation condition of laser tight L or a material of a portion to be irradiated with laser light L, and are about 0.1 to 10 μm, for example.

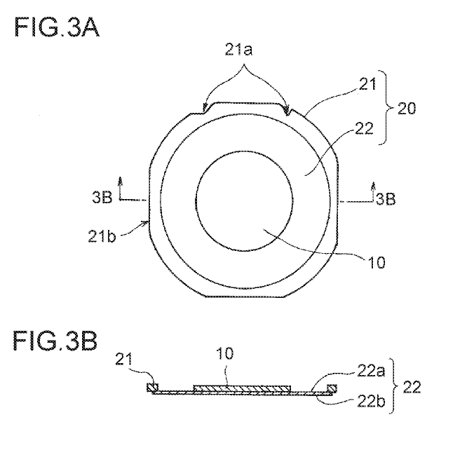

From the viewpoint of handling property, the step after the laser dicing step is performed in a state where second main surface 10Y is supported by supporting member 22. The material of supporting member 22 is not particularly limited Among the materials, when considering that substrate 10 is diced in a state where substrate 10 is supported by supporting member 22, from the viewpoint that element chip 110 to be obtained is easily picked up, supporting member 22 is preferably a flexible resin film. In this case, from the viewpoint of handling property, supporting member 22 is fixed to frame 21 as illustrated in FIGS. 3A and 3B. Hereinafter, frame 21 and supporting member 22 which is fixed to frame 21 are collectively referred to as transfer carrier 20. FIG. 3A is a top surface view illustrating transfer carrier 20 and FIG. 3B is a cross-sectional view of transfer carrier 20 taken along line 3B-3B of FIG. 3A.

The material of the resin film is not particularly limited, and examples thereof include a thermoplastic resin such as polyolefins such as polyethylene and polypropylene and polyester such as polyethylene terephthalate. Various additives such as a rubber component (for example, ethylene-propylene rubber (EPM), ethylene-propylene-diene rubber (EPDM), or the like) for applying stretchability, a plasticizer, a softener, an antioxidant, a conductive material, and the like may be blended to the resin film. In addition, the thermoplastic resin may have a functional group that exhibits a. photopolymerization reaction such as an acrylic group.

For example, supporting member 22 includes a surface having an adhesive (adhesive surface 22a) and a surface having no adhesive (non-adhesive surface 22b). The outer peripheral edge of adhesive surface 22a is adhered to one surface of frame 21 and covers the opening of frame 21. The substrate 10 is adhered and held on a portion which is exposed from the opening of frame 21 of adhesive surface 22a. When the plasma process is performed, supporting member 22 is mounted on the stage such that the stage (hereinafter, simply referred to as a stage) to be disposed within the plasma processing stage is in contact with non-adhesive surface 22b.

Adhesive surface 22a is preferably formed of the adhesive component in which the adhesive force is reduced by irradiation with an ultraviolet lay (UV). Accordingly, when element chip 110 is picked up after the dicing, element chip 110 is easily peeled off from adhesive surface 22a by performing UV irradiation, element chip 110 is easily picked up. For example, supporting member 22 is obtained by applying a UV curable acrylic adhesive on one surface of a resin film in a thickness of 5 to 20 μm.

Frame 21 is a frame body having an opening with an area equal to or larger than the entire area of semiconductor substrate 10 and has a predetermined width and a substantially constant thin thickness. Frame 21 has the rigidity to extent that holding sheet 22 and semiconductor substrate 10 can be transported in a state where supporting member 22 and semiconductor substrate 10 are held. The shape of the opening of frame 21 is not particularly limited. However, the shape thereof may be a polygon such as a circle, a rectangle, a hexagon, or the like. Notch 21a or corner cut 21b for positioning may be provided in frame 21. Examples of the material of frame 21 include metals such as aluminum and stainless steel, a resin, or the like.

### (3) Protection Film Stacking Step

After the laser dicing step, protection film 13 is stacked on a front surface of second element region 122 and the end surface of element chip 110 (FIG. 1). The stacking of protection film 13 is performed by exposing substrate 10 to second plasma P2, for example. This method is called a plasma CVD, and is excellent in a point that a thin film can be formed at a relatively low temperature and at a high speed. In this time, damaged region DR is also covered with protection film 13.

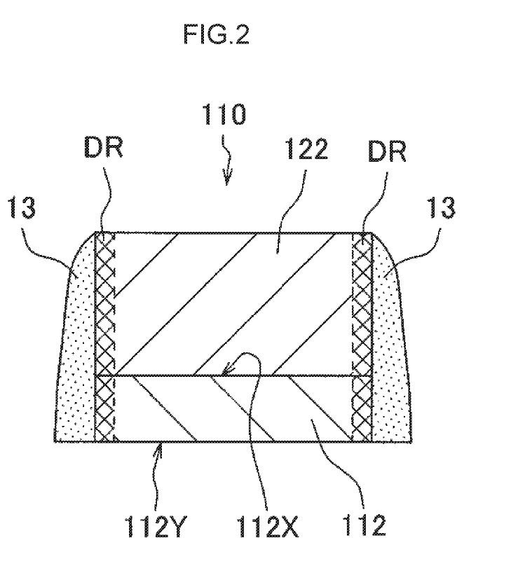

Protection film 13 to be stacked may have insulation properties and the composition thereof is not particularly limited. Protection film 13 may contain inorganic material such as silicon oxide, silicon nitride, or silicon oxynitride, may contain an organic material such as a polymer, or a composite material of the inorganic material and the organic material. Among these materials, when considering a feature that a part of protection film 13 becomes an element for configuring element chip 110 after dicing (refer to FIGS. 2A and 2B), it is preferable that the material is a material having high water repellency and low hygroscopicity. An example of the material includes fluorocarbon.

In order to stack protection film. 13 containing fluorocarbon, plasma which uses a process gas containing fluorocarbon such as CF₄, or C₄F₈ may be used. The thickness of stacking protection film 13 is not particularly limited, and is within a range of 0.5 to 10 μm inclusive, for example. Protection film 13 can be stacked under the conditions that the pressure in vacuum chamber 103 is adjusted to 15 to 25 Pa, power to he inputted from first high frequency power supply 210A to antenna 209 is set to 1500 to 2500 W, and power to be inputted from second high frequency power surface 210B to high frequency electrode portion 220 is set to 50 to 150 W, while supplying 150 sccm of C₄F₈ and 50 sccm of helium (He) as a raw material, for example.

When a process is performed for 300 seconds under the conditions, protection film 13 having a thickness of 3 μm can be formed. In the present exemplary embodiment, as the raw material gas, a mixed gas of C₄F₈ and He is used. By using He, dissociation of C₄F₈ is accelerated in the plasma. As a result, dense protection film 13 with a high adhesion is formed. The sccm is a unit of a flow rate and 1 sccm is an amount of the gas in a standard state (0° C., 1 atmosphere) flowing 1 cm³ per a minute.

As the stacking method of protection film 13, a thermal CVD method, a sputtering method, or the like can be used in addition to the above-described plasma CVD method.

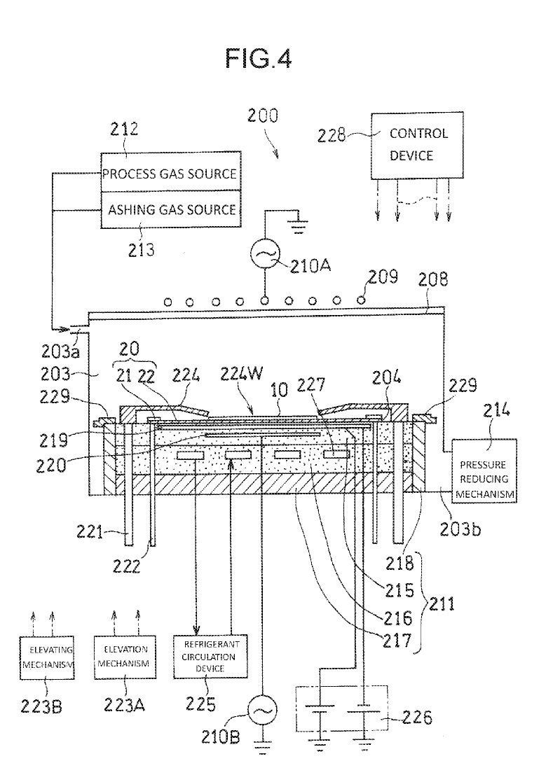

Next, plasma processing device 200 to be used in the plasma CVD and the plasma etching will be described in detail with reference to FIG. 4. However, the plasma processing device is not limited thereto. FIG. 4 schematically illustrates a structure of plasma processing device 200 to be used in the present exemplary embodiment, in a cross-section.

Plasma processing device 200 includes stage 211. Transfer carrier 20 is mounted on stage 211 such that the surface, on which semiconductor substrate 10 of supporting member 22 is held, faces upward. Cover 224 having window portion 224W for covering at least a part of frame 21 and supporting member 22 and for exposing at least a part of substrate 10 is disposed above stage 211.

Stage 211 and cover 224 are disposed inside the reaction chamber (vacuum chamber 203). Vacuum chamber 203 has a roughly cylindrical shape with an upper potion opened and the upper opening is closed by dielectric member 208 that is a lid. As a material configuring vacuum chamber 203, aluminum, stainless steel (SUS), aluminum in which the surface is alumite-processed, and the like can be exemplified. As the material configuring dielectric member 208, a dielectric material such as yttrium oxide (Y₂O₃), aluminum nitride (AlN), alumina (Al₂O₃), quartz (SiO₂), and the like can be exemplified. Antenna 209 as an upper electrode is disposed above dielectric member 208. Antenna 209 is electrically connected to first high frequency power supply 210A. Stage 211 is disposed at the bottom portion side inside vacuum chamber 203.

Gas feed port 203a is connected to vacuum chamber 203. Process gas source 212 and aching gas source 213 that are a supply source of the process gas is connected to gas feed port 203a respectively, by pipes. In addition, exhaust port 203b is provided on vacuum chamber 203, and pressure reducing mechanism 214 including a vacuum pump for evacuating the gas in vacuum chamber 203 and decompressing the gas is connected to exhaust port 203b.

Stage 211 includes electrode layer 215, metal layer 216, base 217 for supporting, electrode layer 215 and metal layer 216, and outer peripheral portion 218 surrounding electrode layer 215, metal layer 216, and base 217 which have substantially circular shape. Outer peripheral portion 218 is configured of the metal layer with conductivity and etching resistance, and protects electrode layer 215, metal layer 216, and base 217 from the plasma. Annular outer peripheral ring 229 is disposed on the upper surface of outer peripheral portion 218. Outer peripheral ring 229 serves to protect the upper surface of outer peripheral portion 218 from the plasma. Electrode layer 215 and outer peripheral ring 229 are configured of, for example, the above-described dielectric material.

An electrode portion (hereinafter, referred to as an ESC electrode 219) for configuring electrostatic suction mechanism and high frequency electrode portion 220 which is electrically connected to second high frequency power surface 210B are disposed inside electrode layer 215. Direct-current power supply 226 is electrically connected to ESC electrode 219. The electrostatic suction mechanism is configured of ESC electrode 219 and direct-current power supply 226.

Metal layer 216 is configured of, for example, aluminum in which an alumite coating is formed on the surface thereof. Coolant flow path 227 is formed in metal layer 216. Coolant flow path 227 cools stage 211. By cooling stage 211, supporting member 22 mounted on stage 211 is cooled and cover 224 in which a part thereof is in contact with stage 211 is also cooled. Accordingly, substrate 10 or supporting member 22 is suppressed from being damaged by being heated during plasma processing. The coolant in coolant flow path 227 is circulated by refrigerant circulation device 225.

A plurality of supporting portions 222 passing through stage 211 is disposed in the vicinity of stage 211. Supporting portion 222 is driven to move up and down by elevation mechanism 223A. When transfer carrier 20 is transported into vacuum chamber 203, transfer carrier 20 is transferred to supporting portion 222 which is raised to a predetermined position. Supporting portion 222 supports frame 21 of transfer carrier 20. The upper end surface of supporting member 22 descends to the same level as stage 211. Accordingly, transfer carrier 20 is mounted on a predetermined position of stage 211.

A plurality of elevating rods 221 are connected to the end portion of cover 224, thereby capable of elevating cover 224. Elevating rod 221 is driven to move up and down by elevating mechanism 223B. The elevating operation of cover 224 by elevating mechanism 223B can be performed independently of elevation mechanism 223A.

Control device 228 controls an operation of an element for configuring plasma processing device 200 including first high frequency power supply 210A, second high frequency power surface 21.0B, process gas source 212, ashing gas source 213, pressure reducing mechanism 214, refrigerant circulation device 225, elevation mechanism 223A, elevating mechanism 223B, and the electrostatic suction mechanism.

### (4) Protection Film Etching Step

After the protection film stacking step, protection film 13 is etched anisotropically by exposing element chip 110 to plasma (first plasma P1) (FIG. 1D). By the anisotropical etching, protection film 13 which is stacked on the front surfaces of supporting member 22 and second element region 122 is removed. On the other hand, protection film 13 for covering the end surface of element chip 110 is remained. That is damaged region DR which is formed on the end surface of element chip 110 is covered with protection film 13.

From the viewpoint of that the etching is easily progressed anisotropically, while high frequency power is applied to high frequency electrode portion 220 and the bias voltage is applied, it is preferable to perform the etching. The etching is performed under the conditions that the pressure in vacuum chamber is adjusted to 0.2 to 1.5 Pa, power to be inputted from first high frequency power supply 210A to antenna 209 is set to 1500 to 2500 W, and power to be inputted from second high frequency power surface 210B to high frequency electrode portion 220 is set to 150 to 300 W, while supplying 150 to 300 sccm of argon (Ar) and 0 to 150 sccm of oxygen (O₂) as a raw material, for example. Under the conditions, protection film 13 can be etched at a range of about 0.5 μm/min.

A cross-section of element chip 110 to be obtained in this manner is illustrated in FIGS. 2A and 2B. Element chip 110 includes a first layer (first element region 112) that is a semiconductor layer having lamination surface 112X and surface 112Y which is located at a side facing lamination surface 112X and a second layer (second element region 122) including insulating film which is laminated on lamination surface 112X. Damaged region DR is formed in the vicinity of the end surfaces of first element region 112 and second element region 122. The end surfaces of first element region 112 and second element region 122 are covered with protection film 13 which is formed so as to surround the outer periphery of element chip 110. That is, element chip 110 includes damaged region DR and damaged region DR is covered with protection film 13 is included in element chip 110. Therefore, when element chip 110 is used, cracks or clips in element chip 110 can be suppressed, even when external force (bending, impact, or the like) is applied. In addition, since an end portion of the boundary (lamination surface 112X) between first element region 112 and second element region 122 is covered with protection film 13, peeling off of second element region 122 and first element region 112 from lamination surface 112X can also he suppressed.

In addition, in the present exemplary embodiment, substrate 10 is diced in a state where substrate 10 is suppressed by supporting member 22. Therefore, after dicing, element chip 110 to be obtained is picked up while peeling off from supporting member 22. Also in this case, since damaged region. DR is not exposed, element chip 110 is picked up without being damaged. Furthermore, oven in a case where element chips 110 are held in close contact with supporting member 22 after the dicing, although protection films 13 of adjacent element chips 110 collides to each other, collision in first element regions 112 can be avoided. Therefore, the damage to first element region 112 is further suppressed.

In addition, in damaged region DR which is formed by thermal influence of laser light L, the crystallinity is disturbed. Therefore, the front surface of damaged region DR has fine irregularities. Damaged region DR strongly adheres to protection film 13 by an anchor effect due to the irregularities. That is, protection film 13 is strongly adhered to first element region 112 and second element region 122, respectively. Therefore, peeling off of protection film 13 is suppressed and the inner portion of element chip 110 can be protected. In addition to this, the semiconductor of damaged region DR has a higher reactive than the usual manner and easily absorbs impurities. That is, the impurities (for example, moisture, solder component applied to the front surface of second element region 122, or the like) to be entered from the outside are diffused into third damaged region DR and are captured (absorption or suction) in third damaged region DR3. Therefore, the diffusion of the impurities further inside element chip 110 can be suppressed. Accordingly, the deterioration of performance of element chip 110 is suppressed.

According to the method according to the present disclosure, since the element chip with excellent deflective strength is obtained, the method is useful as a method for manufacturing the element chip from various substrates.

What is claimed is:

1. A method for manufacturing an element chip, comprising:
a step of preparing a substrate which has a first main surface and a second main surface and includes a first layer that is a semiconductor layer, a second layer including an insulating film formed on a side of the first main surface of the first layer, a plurality of element regions, and a dividing region for defining each of the element regions;
a laser dicing step of dividing the substrate to a plurality of element chips including the element regions by irradiating the dividing region with laser light from the side of the first main surface, in a state where the second main surface is supported by a supporting member and forming a damaged region on an end surface of each of the element chips;
a protection film stacking step of stacking a protection film on the first main surface and the end surface of each of the element chips, after the laser dicing step; and
a protection film etching step of removing the protection film stacked on the first main surface through etching the protection film anisotropically by exposing each of the element chips to plasma, after the protection film stacking step and remaining the protection film for covering the damaged region.

2. An element chip comprising:
a first layer that is a semiconductor layer having a lamination surface and a surface facing the lamination surface;
a second layer including an insulating film which is laminated on the lamination surface;
a damaged region formed on end surfaces of the first layer and the second layer; and
a protection film for covering the damaged region formed on the end surfaces of the first layer and the second layer.
